(19) United States
(12) Patent Application Publication
(10) Pub. No.: US 2002/0140446 A1
(43) Pub. Date: Oct. 3, 2002

(54) Method for initiating a heat dissipating fan in a notebook

(76) Inventor: Shao-Tsu Kung, Taipei (TW)

Correspondence Address: NAIPO (NORTH AMERICA INTERNATIONAL PATENT OFFICE), P.O. BOX 506, MERRIFIELD, VA, 22116, US

(21) Appl. No.: 09/819,754

(22) Filed: Mar. 29, 2001

(51) Int. Cl. G01R 31/02

(52) U.S. Cl. 324/760

(57) ABSTRACT

An embedded controller outputs a predefined initiation signal to initiate a heat dissipating fan. If the temperature of the CPU does not have a predetermined drop, the embedded controller will output a pulse width modulated (PWM) signal that is different from the preceding initiation signal to start the heat dissipating fan and overcome a phase death angle problem

### BACKGROUND OF THE INVENTION

1. Field of the Invention

The present invention relates to a notebook, and more specifically to a method for initiating a heat dissipating fan in a notebook.

2. Description of the Prior Art

In a notebook, a controller can output a direct current (DC) initiation signal to initiate a dissipating fan. When initiating the dissipating fan, a phase exists between an axle of the dissipating fan and a magnet, so causing the axle of the dissipating fan to be oriented at a magnetic phase death angle. Thus, the DC initiation signal output to the dissipating fan is not capable of initiating the dissipating fan.

Please refer to FIG. 1 of a functional block diagram of a prior art computer system 100. The computer system 100 comprises a central processing unit (CPU) 10, a heat dissipating fan 12 for dissipating heat generated by the CPU 10, and a controller 16 electrically connected to the CPU 10 and the heat dissipating fan 12 for controlling rotations of the heat dissipating fan 12.

As shown in FIG. 1, when the computer system 100 is initiated and the CPU 10 starts to operate, the controller 16 is capable of outputting a direct current (DC) initiation signal to initiate a dissipating fan 12 for dissipating heat generated by the CPU 10. The DC initiation signal output to the dissipating fan 12 is not capable of initiating the dissipating fan 12 because of the magnetic phase death angle.

For this reason, the present invention provides a method for initiating a heat dissipating fan in a computer system to solve the above mentioned problems.

### SUMMARY OF THE INVENTION

It is therefore a primary objective of this invention to provide a method for initiating a heat dissipating fan in a computer system.

According to the claimed invention, a computer system comprises a central processing unit (CPU), a temperature sensor for detecting the temperature of the CPU, a heat dissipating fan for dissipating heat generated by the CPU, and an embedded controller electrically connected to the temperature sensor and the heat dissipating fan for controlling rotations of the heat dissipating fan. The method is performed by using the embedded controller to output a predefined initiation signal to initiate the heat dissipating fan. If the temperature of the CPU continually increases and does not decrease below a predetermined temperature within a predetermined time period, the embedded controller will output a pulse width modulated (PWM) signal that is different from the preceding initiation signal to start the heat dissipating fan.

It is an advantage of the present invention that the computer system uses the embedded controller to output the pulse width modulated (PWM) signal that is different from the preceding initiation signal to start the heat dissipating fan. Therefore, the computer does not experience the problems that occur due to a magnetic phase death angle.

These and other objectives and advantages of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a prior art computer system.

FIG. 2 is a functional block diagram of a first preferred embodiment of the present computer system.

FIG. 3 is a functional block diagram of a second preferred embodiment of the present computer system.

### DETAILED DESCRIPTION OF THE PREFERRED EMBODIMENT

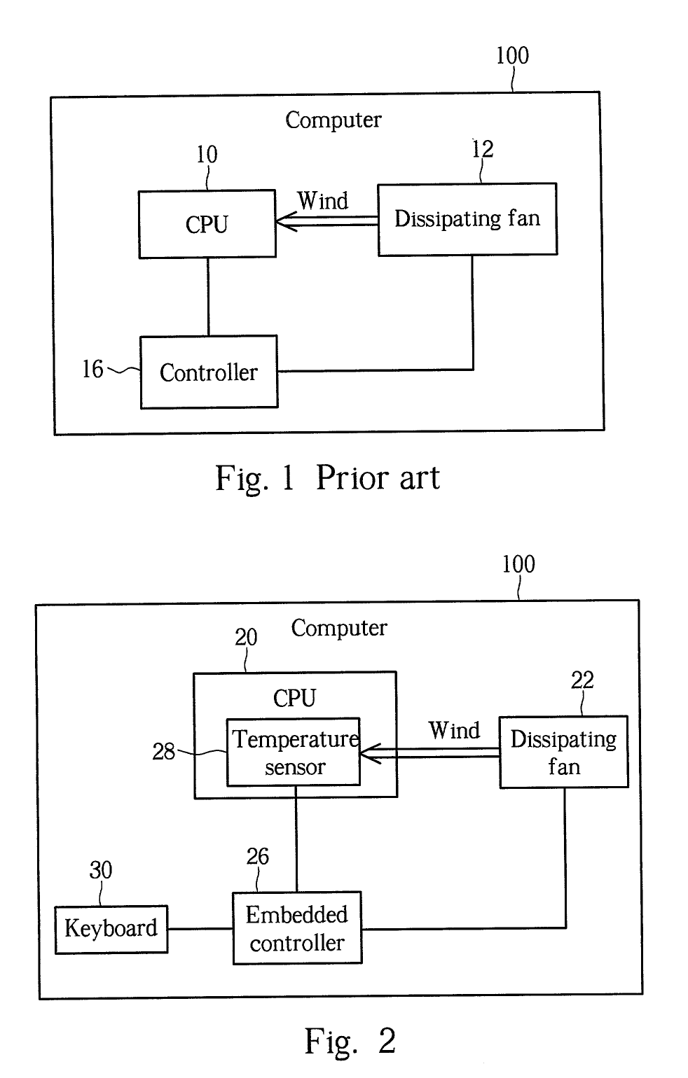

Please refer to FIG. 2 of a functional block diagram of a first preferred embodiment of the present computer system 100. The computer system 100 is a notebook comprising a central processing unit (CPU) 20, a dissipating fan 22, an embedded controller 26, and a temperature sensor 28.

The temperature sensor 28 of the computer system 100 is located within the CPU 20 or the embedded controller 26 for detecting the temperature of the CPU 20. The heat dissipating fan 22 is electrically connected to the embedded controller 26 for dissipating heat generated by the CPU 20. The embedded controller 26 is electrically connected to the temperature sensor 28 and the heat dissipating fan 22 for controlling a keyboard 30 of the computer system 100 and rotations of the heat dissipating fan 22 manipulated by an output of the temperature sensor 28.

When the computer system 100 is switched on or the temperature sensor 28 detects that the temperature of the CPU 20 exceeds a predetermined temperature, the CPU 20 will use the embedded controller 26 to initiate the heat dissipating fan 22 by use of a method described below.

The method for initiating a heat dissipating fan 22 of the computer system 100 comprises the following steps:

1. To use the embedded controller 26 to output a predetermined initiation signal to initiate the heat dissipating fan 26, with the predetermined initiation signal being a direct current (DC) signal or a pulse width modulation (PWM) signal.

2. If the temperature sensor 28 detects that the CPU 20 does not continually increases and does not decrease below a certain temperature within a predetermined time period, the embedded controller 26 will output a PWM signal, that is different from a previous initiation signal to initiate the heat dissipating fan 22.

3. Repeating step 2 until the CPU 20 achieves the predetermined temperature difference or the heat dissipating fan 22 cannot be initiated for a predetermined period of time.

An advantage of this method is when the CPU 20 does not reach a predetermined temperature decrease within a predetermined time period, the embedded controller 26 will output the PWM signal which is different from a previous initiation signal to initiate the heat dissipating fan 22. This method enables the heat dissipating fan 22 to escape a magnetic phase death angle.

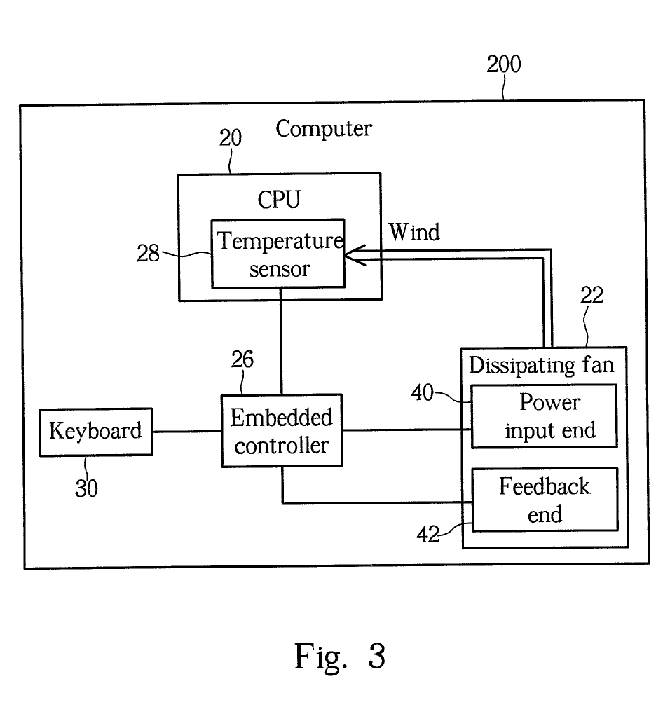

Please refer to FIG. 3 of a functional block diagram of a second preferred embodiment of the present computer system 200. The difference between the method employed in the computer 200 and employed in the computer 100, is that the heat dissipating fan 22 of the computer 200 further comprises a power input end 40 and a feedback end 42. The embedded controller 26 is electrically connected to the power input end 40 and the feedback end 42 of the heat dissipating fan 22.

When the computer system 200 is switched on or the temperature sensor 28 detects that the temperature of the CPU 20 exceeds a predetermined temperature, the CPU 20 will use the embedded controller 26 to initiate the heat dissipating fan 22 by using the method described below.

The method for initiating the heat dissipating fan 22 of the computer system 200 comprises the following steps:

1. To use the embedded controller 26 to output a predetermined initiation signal to initiate the heat dissipating fan 26, and the predetermined initiation signal is a DC signal or a PWM signal.

2. If the embedded controller 26 cannot detect that the heat dissipating fan 22 has been initiated from the feedback end 42 within a predetermined time period, the embedded controller 26 will output a PWM signal which is different from a previous initiation signal to initiate the heat dissipating fan 22.

3. Repeating step 2 until the heat dissipating fan 22 is initiated or the heat dissipating fan 22 cannot be initiated for a predetermined period of time.

An advantage of the first embodiment method is when the embedded controller 26 cannot detect that the heat dissipating fan 22 has been initiated from the feedback end 42, the embedded controller 26 will output the PWM signal which is different from a previous initiation signal to initiate the heat dissipating fan 22. In this situation, the heat dissipating fan 22 is able to escape the magnetic phase death angle.

In contrast to the prior art, when the heat dissipating fan 22 of the present computer system 100, 200 cannot be initiated, the embedded controller 26 will continuously output the PWM signal which is different from a previous initiation signal to initiate the heat dissipating fan 22. For this reason, the computer systems 100, 200 do not experience the problem of magnetic phase death angle resulting in the dissipating fan 22 not being initiated.

The above disclosure is not intended as limiting. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for initiating a heat dissipating fan of a computer, the computer comprising:
an electronic device;
a temperature sensor for detecting a temperature of the electronic device;
a heat dissipating fan for dissipating heat generated by the electronic device; and
a controller electrically connected to the temperature sensor and the heat dissipating fan for controlling rotations of the heat dissipating fan;
the method comprising following steps:
(a) using the controller to output a predetermined initiation signal to initiate the heat dissipating fan; and
(b) if the temperature sensor detects that the electronic device does not reach a predetermined temperature drop within a predetermine time period, the controller will output a pulse width modulation signal which is different from a previous initiation signal to initiate the heat dissipating fan.

2. The method of claim 1 further comprising:
(c) repeating step (b) until the electronic device reaches the predetermined temperature drop or the fan cannot be initiated for a predetermined period of time.

3. The method of claim 1 wherein the predetermined initiation signal is a DC signal or a pulse width modulation signal.

4. The method of claim 1 wherein the electronic device is a central processing unit (CPU), and the temperature sensor is installed inside the CPU.

5. The method of claim 4 wherein when the temperature sensor detects that the temperature of the CPU exceeds a predetermined temperature, the CPU will use the controller to initiate the heat dissipating fan.

6. The method of claim 1 wherein the controller is an embedded controller for controlling a keyboard of the computer.

7. The method of claim 1 wherein the computer is a notebook computer.

8. A method for initiating a heat dissipating fan of a computer, the computer comprising:
an electronic device;
a heat dissipating fan for dissipating heat generated by the electronic device, the heat dissipating fan having a power input end and a feedback end; and
a controller electrically connected to the power input end and the feedback end of the heat dissipating fan for controlling rotations of the heat dissipating fan;
the method comprising following steps:
(a) using the controller to output a predetermined initiation signal to the power input end of the heat dissipating fan to initiate the heat dissipating fan; and
(b) if the controller cannot detect that the heat dissipating fan has initiated from the feedback end within a predetermine time period, the controller will output a pulse width modulation signal which is different from a previous initiation signal to initiate the heat dissipating fan.

9. The method of claim 8 further comprising:
(c) repeating step (b) until the heat dissipating fan is initiated or the fan cannot be initiated for a predetermined period of time.

10. The method of claim 8 wherein the predetermined initiation signal is a DC signal or a pulse width modulation signal.

11. The method of claim 8 wherein the electronic device is a central processing unit (CPU).

12. The method of claim 11 wherein the CPU comprises a temperature sensor, when the temperature sensor detects that the temperature of the CPU exceeds a predetermined temperature, the CPU will use the controller to initiate the heat dissipating fan.

13. The method of claim 8 wherein the controller is an embedded controller for controlling a keyboard of the computer.

14. The method of claim 8 wherein the computer is a notebook computer.
